(19) United States
(12) Patent Application Publication
(10) Pub. No.: US 2009/0307563 A1
(43) Pub. Date: Dec. 10, 2009

(54) REPLACING BAD HARD DRIVE SECTORS USING MRAM

(75) Inventors: Mary A. Marquez, Tucson, AZ (US); Gregg S. Lucas, Tucson, AZ (US); Craig A. Klein, Tucson, AZ (US); Michael L. Harper, Tucson, AZ (US); Robert E. Medlin, Tucson, AZ (US)

Correspondence Address: Connolly Bove Lodge & Hutz LLP, Suite 1100, 1875 Eye Street, NW, Washington, DC, 20006, US

(73) Assignee: IBM Corporation (Almaden Research Center), San Jose, CA (US)

(21) Appl. No.: 12/133,420

(22) Filed: Jun. 5, 2008

(51) Int. Cl. G11C 29/04; G06F 11/22

(52) U.S. Cl. 714/769; 714/E11.145

(57) ABSTRACT

A method of a method of replacing bad sectors in a Hard Disk Drive comprises detecting bad sectors on the Hard Disk Drive; remapping the bad sectors to an auxiliary data storage device comprising an Magnetoresistive Random Access Memory connected to the Hard Disk Drive; and storing data on the auxiliary storage device.

### BACKGROUND

The present invention relates to computer hardware and data storage in particular. Hard Disk Drives are ubiquitous within computer systems, as they provide low cost, voluminous data storage that can be accessed quickly in any order (termed random access). Data are stored on a magnetic disk by a write head that induces a magnetic field that creates a particular localized magnetic polarization on the magnetic surface of the rotating disk in one of two directions. One direction is defined as a logical ‘0’, and the other a logical ‘1’. The disk rotates at a fixed speed and the read/write head assembly is mounted on an arm that is actuated such that it can move radially or semi-radially across the disk as it rotates. To read the stored data, the read head senses the instantaneous polarization of the magnetic field of the magnetic disk at the locations previously written. Hard Disk Drives (HDDs) routinely have bad sectors due to manufacturing media defects, as it would be prohibitively expensive to produce disk drives with no defects.

FIG. 1 is a schematic view of a conventional HDD 100 comprising a processor 101, which uses an SRAM memory 102 and a flash memory 130 to store code and data. The processor 101 is connected to a digital-to-analog converter 104, a voice coil motor driver 106, and a voice coil motor actuator 108, which are used by the processor to maneuver a read/write head assembly over the rotating platter of the HDD (shown in FIG. 2). The HDD 100 further comprises a spindle controller 110 and a spindle motor 112, which are used to control the rotation of the HDD platter. The HDD 100 also has a data-I/O interface 114 with an I/O channel 118 connected to a set of arm electronics 120 by a cable 119 and a slider 122 connected to the arm electronics 120 via a flexible cable 121. The HDD 100 also comprises a host device interface 116 and an RS 232/422 124 interface for communicating with the host device and external devices respectively. These components make up the data path to the HDD disk media.

As further depicted in FIG. 2, HDD 100 also comprises a rotating magnetic disk 200, and an armature 212, which moves read/write head 222 semi-radially across disk 200. When read/write head 222 is positioned for data access, disk 200 rotates under head 222, and a circular track 224 passes underneath head 222. The disk comprises thousands of these concentric tracks, where data are written and read. Two of these tracks are depicted as track 220 and track 230. Tracks are divided into sections called sectors, each typically sized to hold 512 bytes of data. Sectors may also include a sector header containing housekeeping and status information, and error correction code (ECC) data, allowing the correction of a limited number of bits in case of read errors. Two such sectors are shown as sector 204, located on track 230, and sector 206, located on track 220. Conventionally, because sector 206 is located on a track concentrically close to the outside of disk 200, it may be designated as an alternate track. Similarly, because sector 204 is located in the relative middle concentrically of the disk 200, it may be a normally addressed data sector. Sectors are accessed according to a Logical Block Addressing (LBA) scheme, whereby each sector is assigned an address, typically incremented by relative position within a track, then by track location concentrically progressing. Disk 200 may actually comprise multiple disks vertically stacked upon one another with multiple heads interleaved between disks. A single disk is depicted for descriptive clarity.

In operation, if sector 204 is found during manufacturing or in subsequent use to be defective, it may be marked bad by the HDD 100 within its defect table, and sector 206, as an alternate sector, may be defined within the defect table as the alternate location to store data intended for sector 204. This allows the HDD 100 to manage bad sectors without involvement from the computer operating system or file system. Because sector 204 and sector 206 are on different tracks, the read/write head 222 must be moved from track 230 to track 220 in order to access sector 206. This creates a significant but necessary performance penalty for the use alternate sectors on the disk 200. Because the disk drive must move the head assembly to the alternate sector location, wait for the sector to rotate under the read/write head, read or write the data, and then seek back to the original track to continue the transaction, and then wait for the next sector to rotate back under the read/write head assembly, it causes a significant delay in the sequential read or write operation, often a penalty of many milliseconds.

There is a need, therefore, for a way to replace bad sectors on a hard disk drive without the penalty of an increase in access times.

### SUMMARY

The present invention is directed to a method of replacing bad sectors in a hard disk drive utilizing a Magnetoresistive Random Access Memory (MRAM) device as a dedicated spare to replace bad sectors causing no decrease in total storage capacity of the disk. MRAM is a non-volatile technology, which retains information when power is removed. The technology is preferred over Flash technology due to the limited number of write/erase cycles inherent in Flash technology as well as the need to perform read/modify writes to Flash, whereas MRAM technology can be randomly written and read an unlimited number of times.

MRAM technology uses magnetic charge to store data instead of an electrical charge and is advantageous in that it is highly scalable, does not degrade over time due to the number of times it is written (like flash technologies do), has relatively low power requirements, is highly reliable, and cost-effective. Write cycle speeds are in the neighborhood of 35 nanoseconds. Unlike conventional RAM solid-state chip technologies, in MRAM, data is stored by magnetic storage elements. The elements are formed from two ferromagnetic plates, each of which can hold a magnetic field, separated by a thin insulating layer. One of the two plates is a permanent magnet set to a particular polarity, the other's field will change to match that of an external field. A memory device is built from a grid of such “cells”. Reading is accomplished by measuring the electrical resistance of the cell.

A particular cell is (typically) selected by powering an associated transistor which switches current from a supply line through the cell to ground. Due to the magnetic tunnel effect, the electrical resistance of the cell changes due to the orientation of the fields in the two plates. By measuring the resulting current, the resistance inside any particular cell can be determined, and from this the polarity of the writable plate. Typically, if the two plates have the same polarity this is considered to mean “0”, whereas if the two plates are of opposite polarity the resistance will be higher and this means “1”. Data is written to the cells using a variety of means. In the simplest, each cell lies between a pair of write lines arranged at right angles to each other, above and below the cell. When current is passed through them, an induced magnetic field is created at the junction, which the writable plate picks up.

In one embodiment of the invention, a method of replacing bad sectors in an HDD comprises detecting bad sectors on the hard disk drive; remapping the bad sectors to an auxiliary data storage device comprising an MRAM connected to the processor within the hard disk drive; and storing data on the auxiliary storage device. An added side benefit is the elimination of the reserved alternate sectors on the disk media, freeing space for general usage.

### BRIEF DESCRIPTION OF THE DRAWINGS

FIG. 1 is a schematic depicting a prior art Hard Disk Drive;

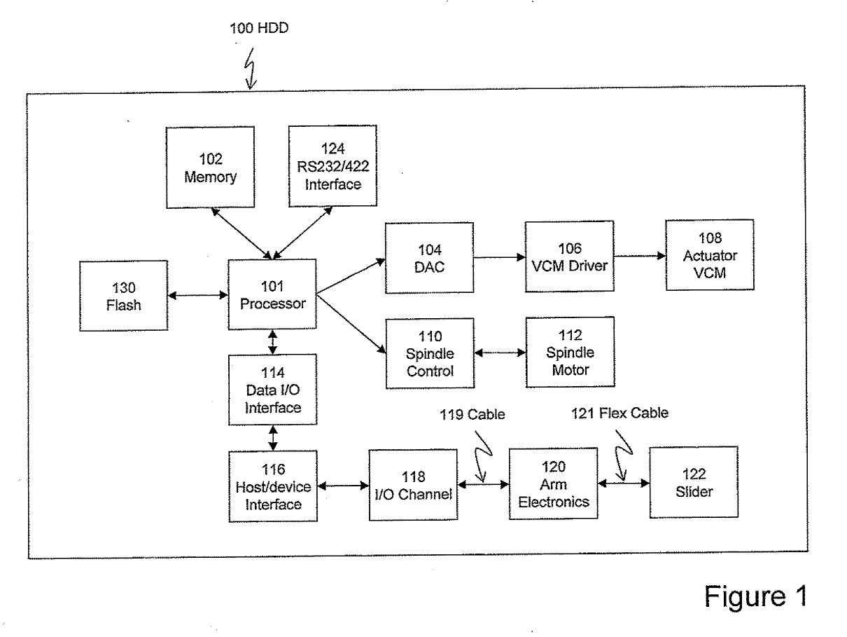

FIG. 2 is a high level drawing of a prior art Hard Disk;

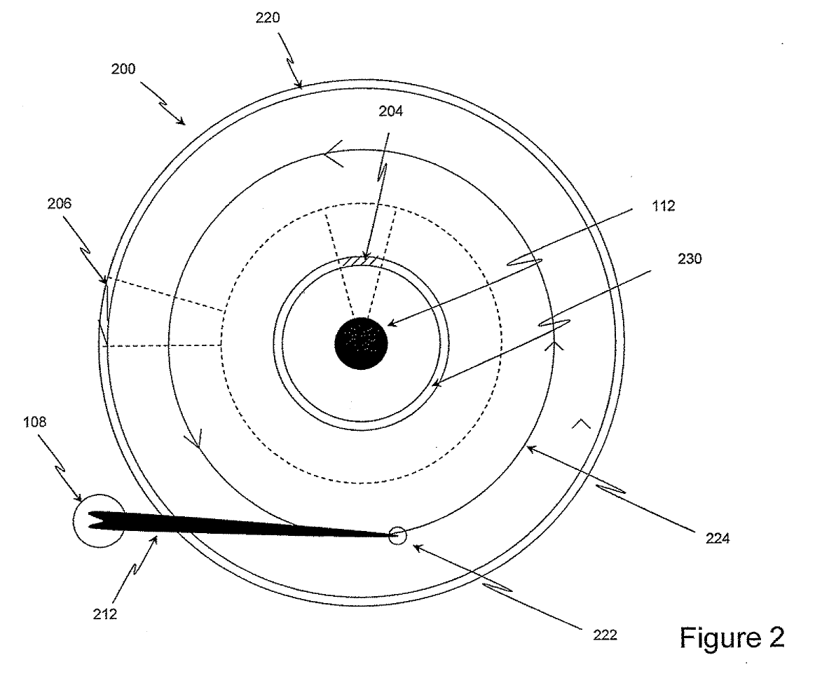

FIG. 3 is a schematic depicting a Hard Disk Drive including an MRAM in accordance with an embodiment of the invention;

FIG. 4 is a high level drawing of a Hard Disk in accordance with an embodiment of the invention, and;

FIG. 5 is a high-level diagram depicting a process in accordance with an embodiment of the invention.

### DETAILED DESCRIPTION

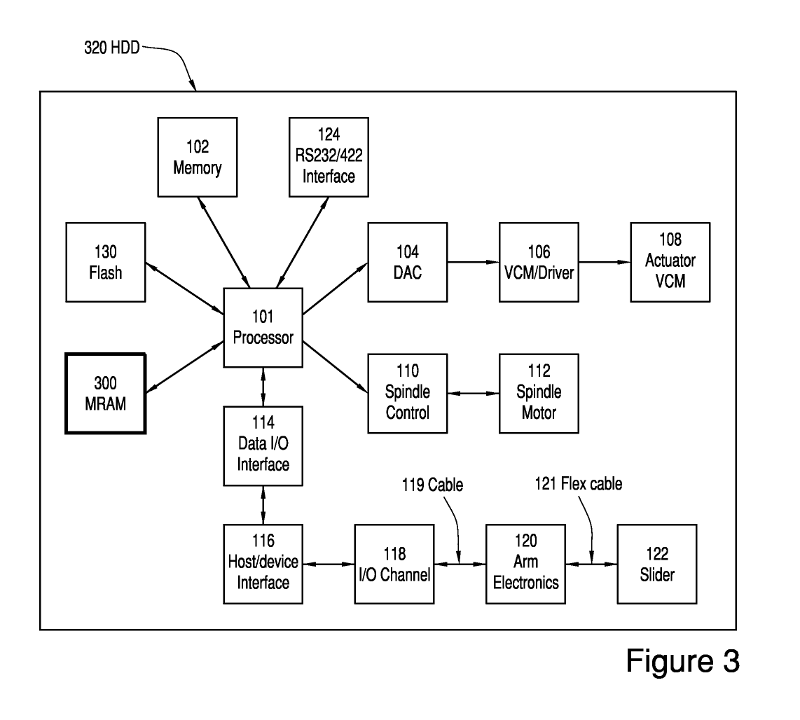

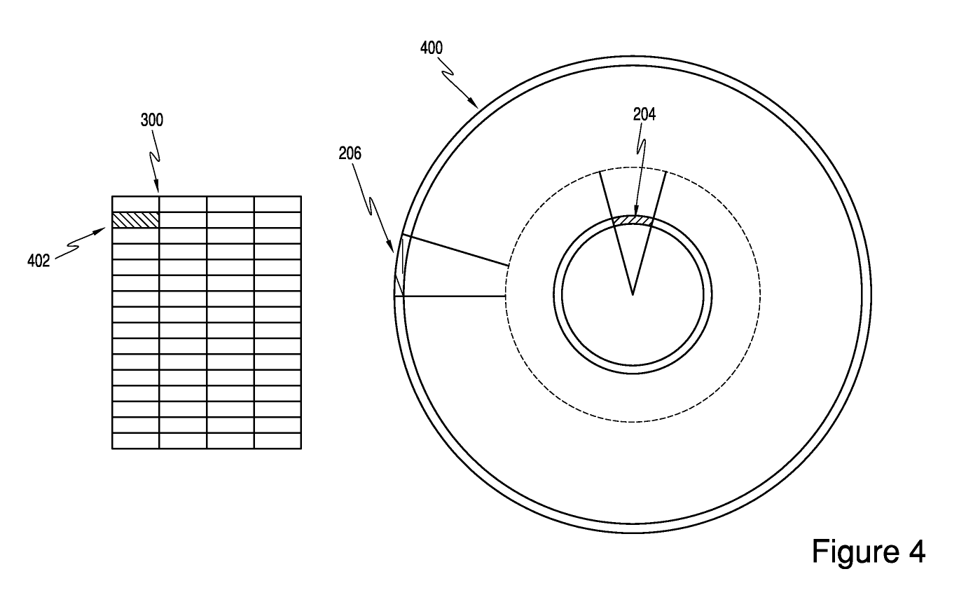

FIG. 3 depicts an HDD according to an embodiment of the present invention. As depicted therein, an HDD 320 comprises a processor 101 connected to MRAM 300, which acts as a non-volatile random access data store, and SRAM memory 102 and flash memory 130 to store code and data. Processor 101 is connected to a digital-to-analog converter 104, a voice coil motor driver 106, and a voice coil motor actuator 108, which are used by the processor to maneuver a read/write head assembly over a rotating platter 400 of the HDD 200 (shown in FIG. 4). The HDD 320 further comprises a spindle controller 110 and a spindle motor 112, which are used to control the rotation of the HDD platter 400. The HDD 320 also has a data-I/O interface 114 with an I/O channel 118 connected to a set of arm electronics 120 by a cable 119 and a slider 122 connected to the arm electronics 120 via a flexible cable 121. The HDD 320 also comprises a host device interface 116 and an RS 232/422 124 interface for communicating with the host device and external devices respectively.

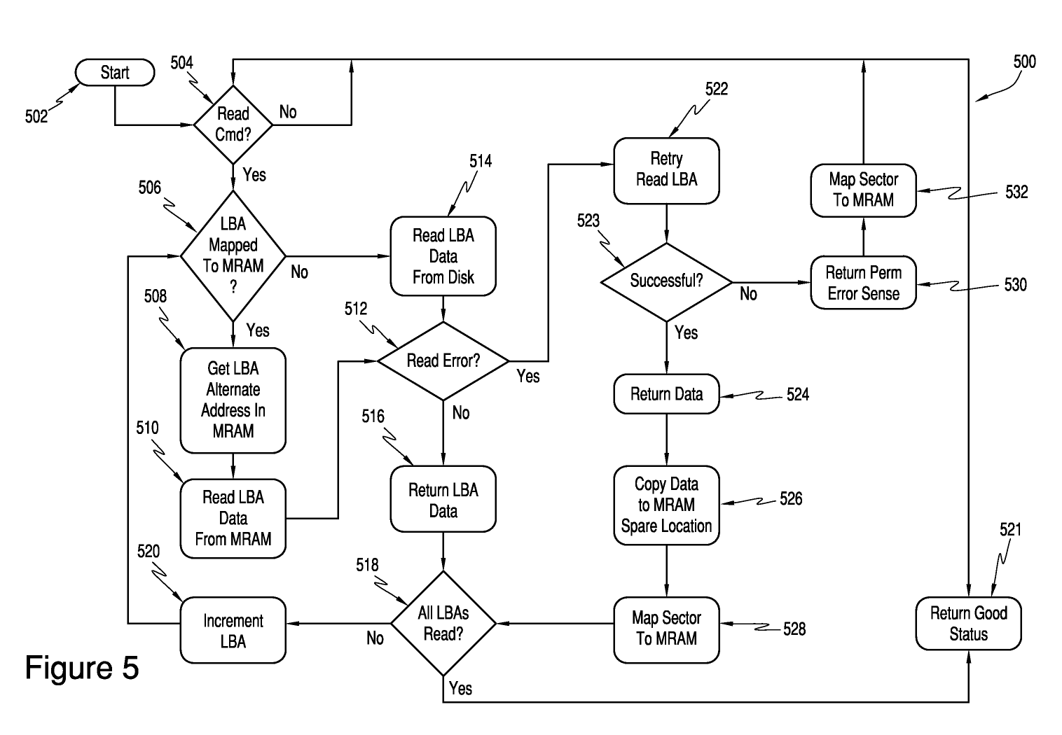

FIG. 4 depicts rotating platter 400 of HDD 320 of FIG. 3 and MRAM 300. MRAM 300 is logically divided into blocks, each addressable as a logical block. The logical blocks within MRAM 300 have a data area defined equal to size of the data area on the sectors located on disk 400. The MRAM logical blocks may also have addition length allocated for ECC data, and/or a sector header. Logical block 402 is one of the logical blocks within MRAM 300. If sector 204 is found to be defective, logical block 402 may be assigned as the alternate storage location for sector 204's data. When data access is requested from sector 204, HDD 320 instead accesses MRAM logical block 402. Because MRAM 300 is a solid state memory device, it does not have the performance penalty associated with the movement of the read/write head 222, so subsequent sectors located on track 230 can be accessed immediately as they pass under the read/write head 222. In operation, when bad sectors are identified in HDD 320, the locations of the bad sectors are re-mapped to the MRAM device 300. The remapping process by which bad sector locations are remapped from disk 200 to the MRAM device 300 is depicted in FIG. 5.

As depicted therein, the remapping process begins with step 502 and flows to 504 where it checks for any Read commands from the host device interface 116. If a Read command has not been received (no), the process returns to check again at step 504. If a Read command is received (yes) the process moves to step 506, where the process checks whether the first LBA to be read has been mapped to an alternate location in MRAM 300. If the sector has not been remapped to MRAM 300 (no), the process flows to step 514, where the LBA data are read from the disk 320. The process continues at step 512, where it checks if the read was successful. The data may have been read without errors, or it may have been read with errors, but corrected using the associated error correction code (ECC) stored with the data, either way it constitutes a successful read.

In an alternate embodiment, the HDD 320 may return the ECC-recovered data and subsequently remap the sector. Having read the data without a read error (no), the process continues at step 516, where the data read are returned to the requesting command initiator. The process then checks in step 518 whether all LBAs have been read. If all LBAs have been read (yes), the process returns good status to the command initiator in step 521, and then returns to step 504. If in step 518 it is determined that not all LBA's requested have been read (no), the process moves to step 520, where the LBA is incremented and the process continues at step 506 as previously described. If in step 506 it is determined that the requested LBA is mapped by the HDD 320 to the MRAM device 300 (yes), the alternate block address in MRAM 300 is obtained from the defect table in step 508, and the LBA data are read from their alternate location in MRAM 300 instep 510. The process then flows to step 512 as previously described.

If in step 512 it is determined that a read error occurred (yes), the process moves to step 522, and the read is retried. In step 523, a check is made for success. If the read retry was successful (yes) the process returns the data requested to the command initiator in step 524, and then flows to step 526, where it copies the data read from the sector to a spare location in MRAM 300. The defect table is updated in step 528, and the bad sector is remapped to MRAM device 300. The process then flows to step 518 as previously described. If in step 523 it is determined that the read retry was unsuccessful (no), in step 530 the HDD 320 returns sense to the command initiator indicating that a permanent read error has occurred. The process continues at step 532, where the defect table is updated mapping the defective sector to MRAM 300. The process then returns to step 504.

It should be noted that the embodiment described above is presented as one of several approaches that may be used to embody the invention. It should be understood that the details presented above do not limit the scope of the invention in any way; rather, the appended claims, construed broadly, completely define the scope of the invention.

What is claimed is:

1. A method for eliminating the performance penalty associated with mapping of defective data sectors for a Hard Disk Drive storage comprising:
detecting bad sectors on the Hard Disk Drive;
remapping the bad sectors to an auxiliary data storage device comprising MRAM connected to the Hard Disk Drive; and
storing data on the auxiliary storage device.
